(19) United States
(12) Patent Application Publication
(10) Pub. No.: US 2026/0050210 A1
(43) Pub. Date: Feb. 19, 2026

(54) RESIST COMPOSITION AND METHOD FOR PRODUCING SAME

(71) Applicant: NIPPON SHOKUBAI CO., LTD., Osaka (JP)

(72) Inventor: Akira NISHIMURA, Osaka (JP)

(73) Assignee: NIPPON SHOKUBAI CO., LTD., Osaka (JP)

(21) Appl. No.: 19/129,795

(22) PCT Filed: Dec. 1, 2023
(86) PCT No.: PCT/JP2023/043095

§ 371 Date: May 14, 2025

(30) Foreign Application Priority Data
Dec. 8, 2022 (JP) 2022-196306

(51) Int. Cl. G03F 7/004

(52) U.S. Cl. CPC G03F 7/0042

(57) ABSTRACT

To provide a resist composition having high sensitivity and being able to form a pattern with a low exposure amount. A resist composition containing an organic tin compound and an organic boron compound represented by the following formula. (In the formula, R¹, R², and R³ each independently represent an organic group that bonds to boron by a carbon atom, an oxygen-containing organic group that bonds to boron by an oxygen atom, or OH. The oxygen-containing organic group may contain a boron atom. Two groups selected from the group consisting of R¹, R², and R³ may link to form a ring structure.)

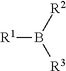

### TECHNICAL FIELD

The present invention relates to a resist composition and a method for producing the same.

### BACKGROUND ART

A resist composition is known to contain a metal-containing compound. For example, Non-Patent Document 1 describes a resist composition containing a compound containing a tin-oxo cage and OH, an acetate anion, a malonate anion, or a tosylate anion.

### CITATION LIST

### Non-Patent Literature

Non-Patent Document 1: Jarich Haitjema et al., “Extreme ultraviolet patterning of tin-oxo cages”, J. Micro/Nanolith. MEMS MOEMS., 16 (3), 033510 (2017)

### SUMMARY OF INVENTION

### Technical Problem

However, the resist composition described in Non-Patent Document 1 has insufficient sensitivity, and considerable exposure is required to form a resist film (resist pattern).

### Solution to Problem

As a result of diligent research to solve the issue described above, the inventor of the present invention found that a resist composition containing an organic tin compound and a predetermined organic boron compound has high sensitivity and can form a pattern with a low exposure amount, and thus completed the present invention.

Accordingly, the present invention includes the following constitution.

[1] A resist composition containing:
an organic tin compound; and
an organic boron compound represented by a formula below:

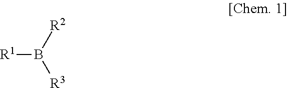

In the formula, R¹, R², and R³ each independently represent an organic group that bonds to boron by a carbon atom, an oxygen-containing organic group that bonds to boron by an oxygen atom, or OH. The oxygen-containing organic group may contain a boron atom. Two groups selected from the group consisting of R¹, R², and R³ may link to form a ring structure.

[2] The resist composition according to [1] above, where the organic tin compound contains a Sn—O bond and a Sn—C bond.

[3] The resist composition according to [1] or [2] above, where the organic tin compound is a tin cluster.

[4] The resist composition according to any one of [1] to [3] above, where the tin cluster contains a cation-type tin cluster and a counter anion.

[5] The resist composition according to any one of [1] to [4] above, where at least one of R¹, R², or R³ described above is an organic group that bonds to boron by a carbon atom, and at least one of R¹, R², or R³ described above is an oxygen-containing organic group that bonds to boron by an oxygen atom.

[6] The resist composition according to any one of [1] to [5] above, where the organic boron compound contains at least one type selected from the group consisting of boronic acid, boronate ester, and boroxine.

[7] A method for forming a resist pattern, the method including:
a step (i) of applying the resist composition described in any one of [1] to [6] above;
a step (ii) of drying a coating film of the resist composition;
a step (iii) of exposing the coating film of the resist composition; and
a step (iv) of developing a film of the resist composition.

[8] A method for producing a resist composition, the method including a step of mixing, in an organic solvent, an organic tin compound and an organic boron compound represented by a formula below:

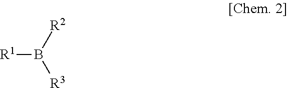

In the formula, R¹, R², and R³ each independently represent an organic group that bonds to boron by a carbon atom, an oxygen-containing organic group that bonds to boron by an oxygen atom, or OH. The oxygen-containing organic group may contain a boron atom. Two groups selected from the group consisting of R¹, R², and R³ may link to form a ring structure.

### Advantageous Effects of Invention

The resist composition of the present disclosure has high sensitivity, and use of the resist composition of the present disclosure can form a pattern with a low exposure amount.

### DESCRIPTION OF EMBODIMENTS

Hereinafter, the present disclosure will be described in detail.

Note that a combination of two or more of preferred embodiments of the present disclosure described below is also a preferred embodiment of the present disclosure.

### Resist Composition

The resist composition of the present disclosure contains an organic tin compound and a predetermined organic boron compound described below.

### Organic Tin Compound

The organic tin compound may be a mononuclear tin or may be a tin cluster (multinuclear tin), and is preferably a tin cluster. Furthermore, the organic tin compound preferably contains a Sn—O bond and a Sn—C bond.

### Mononuclear Tin

The mononuclear tin is not particularly limited, and the mononuclear tin is preferably a mononuclear tin represented by SnR⁴ₓ(OR⁵)_{y}(OCOR⁶)_{z} (with the proviso that x+y+z=4, x is an integer of 1 to 3, y is an integer of 0 to 3, and z is an integer of 0 to 3), and more preferably (x, y, z)=(1, 3, 0), (1, 0, 3), or (2, 0, 2).

In the formula above, R⁴ is an alkyl group that has from 1 to 20 carbons and that may have a substituent, a cycloalkyl group that has from 3 to 20 carbons and that may have a substituent, an alkenyl group that has from 2 to 20 carbons and that may have a substituent, an alkynyl group that has from 2 to 20 carbons and that may have a substituent, an alkenylalkyl group that has from 3 to 20 carbons and that may have a substituent, an alkynyl alkyl group that has from 3 to 20 carbons and that may have a substituent, an aryl group that has from 6 to 30 carbons and that may have a substituent, an aryl alkyl group that has from 7 to 30 carbons and that may have a substituent, or a combination of these. In a case where x is 2, the R⁴ moieties are each independent.

In the formula above, R⁵ is an alkyl group that has from 1 to 20 carbons and that may have a substituent, a cycloalkyl group that has from 3 to 20 carbons and that may have a substituent, an alkenyl group that has from 2 to 20 carbons and that may have a substituent, an alkynyl group that has from 2 to 20 carbons and that may have a substituent, an aryl group that has from 6 to 30 carbons and that may have a substituent, an aryl alkyl group that has from 7 to 30 carbons and that may have a substituent, or a combination of these. In a case where y is 2 or 3, the R⁵ moieties are each independent.

In the formula above, R⁶ is a hydrogen atom, an alkyl group that has from 1 to 20 carbons and that may have a substituent, a cycloalkyl group that has from 3 to 20 carbons and that may have a substituent, an alkenyl group that has from 2 to 20 carbons and that may have a substituent, an alkynyl group that has from 2 to 20 carbons and that may have a substituent, an aryl group that has from 6 to 30 carbons and that may have a substituent, an aryl alkyl group that has from 7 to 30 carbons and that may have a substituent, or a combination of these. In a case where z is 2 or 3, the R⁶ moieties are each independent.

### Tin Cluster

In the present disclosure, the tin cluster is a tin compound in which a plurality of tin atoms is directly linked or indirectly linked by a ligand, and may be a compound having a cage structure. The tin cluster of the present disclosure may optionally contain, as a ligand, one type or two or more types selected from the group consisting of an aqua ligand, a hydroxo ligand, an oxo ligand, a peroxo ligand, a thiolato ligand, a sulfido ligand, a fluoro ligand, a chloro ligand, an iodo ligand, a hydrido ligand, a cyanato ligand, an azido ligand, a carboxylato ligand, and an oxalato ligand. The tin cluster of the present disclosure preferably contains one type or two types selected from the group consisting of an oxo ligand and a peroxo ligand. In the tin cluster, a plurality of tin atoms is more preferably indirectly linked by an oxo ligand and/or a peroxo ligand. For example, in a case where two or more tin atoms are linked by an oxo ligand, a structure such as Sn—O—Sn or Sn—O(—Sn)—Sn is included. Furthermore, in a case where two tin atoms are linked by a peroxo ligand, a structure of Sn—O—O—Sn is included. The tin cluster is preferably a tin-oxo cluster, a tin-peroxo cluster, or a tin-hydroxo cluster, more preferably a tin-oxo cluster or a tin-hydroxo cluster, and even more preferably a tin-oxo cluster.

In the tin cluster of the present disclosure, some or all of the tin atoms are preferably bonded to organic groups. In a case where organic groups are bonded to the tin cluster, it is presumed that organic groups bonded to the tin atoms are cut when exposed, adjacent tin clusters tend to condense at the cut portions as starting points due to presence of a boron compound contained in the organic boron compound, and thus a resist having significantly high sensitivity can be produced.

As the organic group bonded to the tin atom described above, one type or more organic groups selected from the group consisting of alkyl groups, alkenyl groups, and aryl groups are preferred. The alkyl groups and the alkenyl groups described above may be linear, branched, or cyclic. The organic group bonded to the tin atom described above is preferably an organic group having 1 or more and 30 or less carbons, and the organic group may include one or two or more substituents. The organic group bonded to the tin atom described above is preferably an alkyl group, an alkenyl group or an aryl group having 1 or more and 20 or less carbons, more preferably an alkyl group having 1 or more and 20 or less carbons, even more preferably an alkyl group having 1 or more and 10 or less carbons, and particularly preferably an alkyl group having 2 or more and 6 or less carbons.

In a molecule, the tin cluster contains preferably 2 or more tin atoms, and contains preferably 30 or less tin atoms, more preferably 20 or less tin atoms, and even more preferably 18 or less tin atoms.

The tin cluster of the present disclosure is preferably made of a cation-type tin cluster and a counter anion, and the cation-type tin cluster is preferably a divalent cation. The counter anion is preferably a hydroxide ion or an acetate ion.

Specific examples of the tin cluster of the present disclosure include tin clusters of Formula (1) or Formula (2) below. The tin cluster of the present disclosure is preferably a cluster of Formula (1) below.

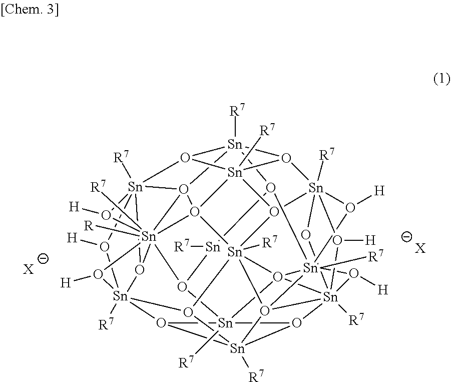

In the formula above, R⁷ represents an organic group that bonds to the tin atom described above, and X⁻ represents a counter anion.

The R⁷ moieties are each independently preferably an alkyl group, an alkenyl group or an aryl group having 1 or more and 20 or less carbons, more preferably an alkyl group having 1 or more and 20 or less carbons, even more preferably an alkyl group having 1 or more and 10 or less carbons, and particularly preferably an alkyl group having 2 or more and 6 or less carbons.

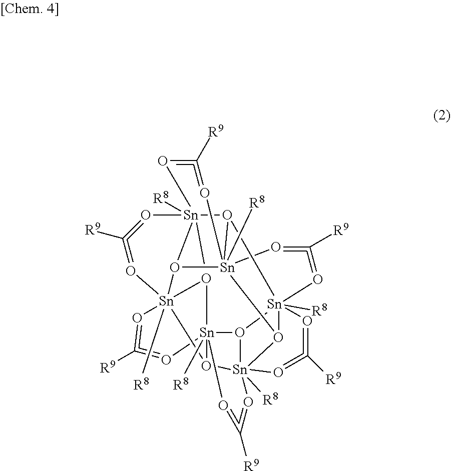

In the formula above, R⁸ represents an organic group that bonds to the tin atom described above, and R⁹ represents an organic group that bonds to a carbon atom.

The R⁸ moieties are each independently preferably an alkyl group, an alkenyl group or an aryl group having 1 or more and 20 or less carbons, more preferably an alkyl group having 1 or more and 20 or less carbons, even more preferably an alkyl group having 1 or more and 10 or less carbons, and particularly preferably an alkyl group having 2 or more and 6 or less carbons. The R⁹ moieties are each independently preferably an alkyl group, an alkenyl group or an aryl group having 1 or more and 20 or less carbons, more preferably an alkyl group having 1 or more and 20 or less carbons, even more preferably an alkyl group having 1 or more and 10 or less carbons, and particularly preferably an alkyl group having 1 or more and 4 or less carbons.

### Organic Boron Compound

The organic boron compound is a compound represented by Formula (3) below (hereinafter, referred to as “organic boron compound of the present disclosure”).

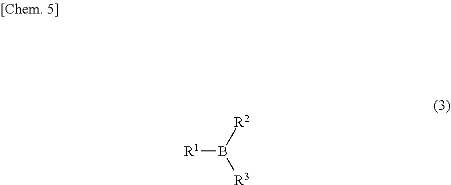

In the formula, R¹, R², and R³ each independently represent an organic group that bonds to boron by a carbon atom, an oxygen-containing organic group that bonds to boron by an oxygen atom, or OH. The oxygen-containing organic group may contain a boron atom. Two groups selected from the group consisting of R¹, R², and R³ may link to form a ring structure.

Preferably, in the organic boron compound of Formula (3) above, at least one of R¹, R², and R³ is an organic group that bonds to boron by a carbon atom, and at least one of R¹, R², and R³ is an oxygen-containing organic group that bonds to boron by an oxygen atom.

The organic boron compound of the present disclosure preferably contains at least one type selected from borate ester, boronic acid, boronate ester, borinic acid, borinate ester, borinic anhydride, boroxine, or a substituted borane, and more preferably contains at least one type selected from the group consisting of boronic acid, boronate ester, and boroxine.

The borate ester refers to a compound in which R¹, R², and R³ in Formula (3) above are each independently an oxygen-containing organic group that bonds to boron by an oxygen atom. The borate ester is preferably at least one type selected from a C₁₋₁₀ alkyl borate ester or a C₆₋₂₀ aryl borate ester. The C₁₋₁₀ alkyl borate ester is preferably at least one type selected from trimethyl borate, triethyl borate, tripropyl borate, or triisopropyl borate. The C₆₋₂₀ aryl borate ester is preferably triphenyl borate.

The boronic acid refers to a compound in which R¹ is an organic group that bonds to boron by a carbon atom and R² and R³ are OH in Formula (3) above. The boronic acid is preferably at least one type selected from an alkyl boronic acid, an alkenyl boronic acid, an alkynyl boronic acid, a cycloalkyl boronic acid, a cycloalkenyl boronic acid, an aryl boronic acid, or a heteroaryl boronic acid, and more preferably at least one type selected from an alkyl boronic acid, a cycloalkyl boronic acid, a cycloalkenyl boronic acid, or an aryl boronic acid.

The alkyl boronic acid is preferably a C₁₋₁₀ alkyl boronic acid, more preferably a C₁₋₇ alkyl boronic acid, and even more preferably at least one type selected from ethylboronic acid, isopropylboronic acid, butylboronic acid, isobutylboronic acid, or hexylboronic acid.

The cycloalkyl boronic acid is preferably a C₃₋₈ cycloalkyl boronic acid, more preferably a C₄₋₇ cycloalkyl boronic acid, and even more preferably at least one type selected from cyclopentylboronic acid or cyclohexylboronic acid.

The cycloalkenyl boronic acid is preferably a C₃₋₈ cycloalkenyl boronic acid, more preferably a C₄₋₇ cycloalkenyl boronic acid, and even more preferably 1-cyclopentenylboronic acid.

The aryl boronic acid is preferably at least one type selected from an aryl monoboronic acid or an aryl diboronic acid. The aryl monoboronic acid is preferably a C₆₋₁₂ aryl monoboronic acid, more preferably a C₆₋₁₀ aryl monoboronic acid, and preferably at least one type selected from phenylboronic acid, 4-methylphenylboronic acid, 4-fluorophenylboronic acid, 3,5-difluorophenylboronic acid, 4-chlorophenylboronic acid, 2-bromophenylboronic acid, 4-cyanophenylboronic acid, 4-methoxyphenylboronic acid, 2,3-dimethoxyphenylboronic acid, 3,4-dimethoxyphenylboronic acid, 4-vinylphenylboronic acid, 4-acetylphenylboronic acid, 3,5-bis(trifluoromethyl)phenylboronic acid, 4-(dimethylamino)phenylboronic acid, 4-isopropylphenylboronic acid, 4-(methoxycarbonyl)phenylboronic acid, 4-(trifluoromethyl)phenylboronic acid, or 1-naphthaleneboronic acid. The aryl diboronic acid is preferably biphenyldiboronic acid, and preferably 4,4′-biphenyldiboronic acid.

The boronate ester refers to a compound in which R¹ is an organic group that bonds to boron by a carbon atom and R² and R³ are each independently an oxygen-containing organic group that bonds to boron by an oxygen atom in Formula (3) above. The boronate ester is preferably an ester of the boronic acid described above, that is, at least one type selected from an alkyl boronate ester, an alkenyl boronate ester, an alkynyl boronate ester, a cycloalkyl boronate ester, a cycloalkenyl boronate ester, an aryl boronate ester, or a heteroaryl boronate ester. Among these, at least one type selected from an alkenyl boronate ester, an alkynyl boronate ester, a cycloalkyl boronate ester, a cycloalkenyl boronate ester, or an aryl boronate ester is more preferred.

The alkenyl boronate ester is preferably a C₁₋₆ alkenyl boronate ester, more preferably a C₂₋₃ alkenyl boronate ester, and even more preferably at least one type selected from 2-allyl-4,4,5,5-tetramethyl-1,3,2-dioxaborolane, diisopropyl allylboronate, 2-vinyl-4,4,5,5-tetramethyl-1,3,2-dioxaborolane, or dibutyl vinylboronate.

The alkynyl boronate ester is preferably a C₁₋₆ alkynyl boronate ester, more preferably a C₁₋₄ alkynyl boronate ester, even more preferably ethynyl boronate ester, and particularly preferably 2-ethynyl-4,4,5,5-tetramethyl-1,3,2-dioxaborolane. The cycloalkyl boronate ester is preferably a C₃₋₈ cycloalkyl boronate ester, more preferably a C₃₋₆ cycloalkyl ester, and even more preferably at least one type selected from 2-cyclopropyl-4,4,5,5-tetramethyl-1,3,2-dioxaborolane or 2-cyclohexyl-4,4,5,5-tetramethyl-1,3,2-dioxaborolane.

The cycloalkenyl boronate ester is preferably a C₃₋₈ cycloalkenyl boronate ester, more preferably a C₄₋₇ cycloalkenyl boronate ester, even more preferably cyclohexenyl boronate ester, and particularly preferably 2-(1-cyclohexenyl)-4,4,5,5-tetramethyl-1,3,2-dioxaborolane.

The aryl boronate ester is preferably a C₆₋₁₂ aryl boronate ester, and preferably at least one type selected from 2-phenyl-4,4,5,5-tetramethyl-1,3,2-dioxaborolane, 2-(4-methylphenyl)-4,4,5,5-tetramethyl-1,3,2-dioxaborolane, 2-(4-fluorophenyl)-4,4,5,5-tetramethyl-1,3,2-dioxaborolane, 2-(3,5-difluorophenyl)-4,4,5,5-tetramethyl-1,3,2-dioxaborolane, 2-(4-chlorophenyl)-4,4,5,5-tetramethyl-1,3,2-dioxaborolane, 2-(2-bromophenyl)-4,4,5,5-tetramethyl-1,3,2-dioxaborolane, 2-(4-cyanophenyl)-4,4,5,5-tetramethyl-1,3,2-dioxaborolane, 2-(4-methoxyphenyl)-4,4,5,5-tetramethyl-1,3,2-dioxaborolane, 2-(2,3-dimethoxyphenyl)-4,4,5,5-tetramethyl-1,3,2-dioxaborolane, 2-(3,4-dimethoxyphenyl)-4,4,5,5-tetramethyl-1,3,2-dioxaborolane, 2-(4-vinylphenyl)-4,4,5,5-tetramethyl-1,3,2-dioxaborolane, 2-(4-acetylphenyl)-4,4,5,5-tetramethyl-1,3,2-dioxaborolane, 2-(3,5-bis(trifluoromethyl)phenyl)-4,4,5,5-tetramethyl-1,3,2-dioxaborolane, 2-(4-(dimethylamino)phenyl)-4,4,5,5-tetramethyl-1,3,2-dioxaborolane, 2-(4-isopropylphenyl)-4,4,5,5-tetramethyl-1,3,2-dioxaborolane, 2-(4-(methoxycarbonyl)phenyl)-4,4,5,5-tetramethyl-1,3,2-dioxaborolane, 2-(4-(trifluoromethyl)phenyl)-4,4,5,5-tetramethyl-1,3,2-dioxaborolane, or 2-(1-naphthalene)-4,4,5,5-tetramethyl-1,3,2-dioxaborolane.

The borinic acid refers to a compound in which R¹ and R² are each independently an organic group that bonds to boron by a carbon atom, and R³ is OH in Formula (3) above. R¹ and R² are each independently preferably a C₁₋₄ alkyl group, a C₄₋₇ cycloalkyl group, or a C₆₋₁₂ aryl group. Specifically, the borinic acid is more preferably at least one type selected from dimethylborinic acid, diethylborinic acid, dipropylborinic acid, diisopropylborinic acid, dibutylborinic acid, ethylbutylborinic acid, dicyclohexylborinic acid, diphenylborinic acid, di(4-fluorophenyl) borinic acid, di(4-methylphenyl) borinic acid, di(4-methoxyphenyl) borinic acid, or di(4-(trifluoromethyl)phenyl) borinic acid.

The borinate ester refers to a compound in which R¹ and R² are each independently an organic group that bonds to boron by a carbon atom and R³ is an oxygen-containing organic group that bonds to boron by an oxygen atom in Formula (3) above. R¹ and R² are each independently preferably a C₁₋₄ alkyl group or a C₆₋₁₂ aryl group, and more preferably a phenyl group. In R³, an amino C₁₋₆ alkyl group preferably bonds to an oxygen atom, an amino C₁₋₄ alkyl group more preferably bonds to an oxygen atom, and an aminoethyl group even more preferably bonds to an oxygen atom. Specifically, the borinate ester is preferably a 2-aminoalkyl diarylborinate, more preferably a 2-aminoalkyl diphenylborinate, and even more preferably 2-aminoethyl diphenylborinate.

The borinic anhydride refers to a compound derived from B₂H₄O by substituting four hydrogen atoms therein with organic groups, where the substituted four organic groups are each an organic group that bonds to boron by a carbon atom. The borinic anhydride is preferably at least one type selected from a dialkyl borinic anhydride or a diaryl borinic anhydride, and more preferably diphenyl borinic anhydride.

The boroxine refers to a compound derived from B₃H₃O₃ by substituting three hydrogen atoms therein with organic groups, where the substituted three organic groups are each an organic group that bonds to boron by a carbon atom or an oxygen-containing organic group that bonds to boron by an oxygen atom. The boroxine is preferably at least one type selected from a trialkoxy boroxine, a triaryl boroxine, or a trialkyl boroxine, and preferably at least one type selected from 2,4,6-triphenylboroxine or 2,4,6-trimethoxyboroxine.

The substituted borane refers to a compound in which three hydrogen atoms bonded to a boron atom of monoborane (BH₃) have been each substituted with R¹, R², or R³, and R¹ to R³ are each independently an organic group that bonds to boron by a carbon atom. The substituted borane is preferably a trisubstituted borane derived from monoborane by substituting three hydrogen atoms with aryl groups that may each have a substituent, and particularly preferably at least one type selected from triphenylborane or tris(pentafluorophenyl) borane.

### Organic Solvent

The resist composition of the present disclosure may contain an organic solvent. Examples of the organic solvent include alcohols, such as ethanol, isopropanol, and 1-butanol; polyhydric alcohols, such as ethylene glycol, diethylene glycol, propylene glycol, and dipropylene glycol; ketones, such as acetone, methyl ethyl ketone, cyclohexanone, methyl isoamyl ketone, and 2-heptanone; esters, such as ethyl acetate, propyl acetate, butyl acetate, methyl lactate, ethyl lactate, methyl pyruvate, ethyl pyruvate, methyl methoxypropionate, ethyl methoxypropionate, methyl ethoxypropionate, ethyl ethoxypropionate, and propylene glycol monomethyl ether acetate; aromatic organic solvents, such as anisole, ethyl benzyl ether, cresyl methyl ether, diphenyl ether, dibenzyl ether, phenetole, butyl phenyl ether, ethylbenzene, diethylbenzene, isopropylbenzene, amylbenzene, toluene, xylene, and trimethyl benzene; lactones, such as γ-butyrolactone; cyclic ethers, such as dioxane; amines, such as N,N-dimethylacetamide; and halogens, such as chloroform, methylene chloride, and benzotrifluoride. One type of the organic solvents may be used alone, or two or more types of the organic solvents may be used in combination. When two or more types of organic solvents are combined, the types and ratio thereof are freely chosen.

### Additional Components

The resist composition of the present disclosure may contain an additional component other than the organic tin compound, the organic boron compound of the present disclosure, and the organic solvent.

### Composition of Resist Composition

Regarding the ratio of tin to boron atoms contained in the resist composition of the present disclosure, an amount of tin with respect to 1 mol of boron atom is preferably from 1 to 1×10⁵ mol, more preferably from 1 to 1000 mol, and even more preferably from 1 to 20 mol. In a case where the ratio is in the range described above, the film quality of the resist film tends to improve.

Regarding the ratio of the organic tin compound to the organic boron compound of the present disclosure contained in the resist composition of the present disclosure, an amount of the organic tin compound with respect to 1 mol of the organic boron compound of the present disclosure is preferably from 0.001 to 5× 10⁴ mol, more preferably from 0.01 to 100 mol, and even more preferably from 0.1 to 10 mol. In a case where the ratio is in the range described above, the film quality of the resist film tends to improve.

The resist composition of the present disclosure contains preferably 1 ppm or greater, more preferably 10 ppm or greater, and even more preferably 100 ppm or greater, of the boron atom. In a case where the amount is in the range described above, the film quality of the resist film tends to improve. Note that, unless otherwise particularly noted in the present invention, “ppm” refers to a value determined based on mass (e.g., 10000 ppm corresponds to 1 mass %).

The resist composition of the present disclosure contains preferably 1 ppm or greater, more preferably 10 ppm or greater, and even more preferably 100 ppm or greater, of tin. The content of tin in the resist composition of the present disclosure is preferably 60 mass % or less, more preferably 50 mass % or less, and even more preferably 40 mass % or less. In a case where the content is in the range described above, the film quality of the resist film tends to improve. Note that the content of boron atom and the content of tin can be typically analyzed by, for example, ICP, ICP-AES, or ICP-MS.

The content of the organic solvent in the resist composition of the present disclosure is not particularly limited and, for example, is only required to be properly set based on coating film thickness or the like. The content of the solvent with respect to 1 mg total of solid content of the resist composition of the present disclosure is preferably 0.005 mL or greater, more preferably 0.01 mL or greater, and even more preferably 0.02 mL or greater. Furthermore, the content of the solvent with respect to 1 mg total of solid content of the resist composition of the present disclosure is preferably 0.30 mL or less, more preferably 0.20 mL or less, and even more preferably 0.10 mL or less. In a case where the content is in the range described above, the film quality of the resist film tends to improve. Note that a total solid content of a resist composition refers to an amount obtained by removing a content of a solvent from a total amount of a resist composition. The total solid content can be measured by a known analytical means, such as liquid chromatography or gas chromatography.

### Method for Producing Resist Composition of Present Disclosure

The resist composition of the present disclosure is preferably produced by the step of mixing an organic tin compound, and the organic boron compound represented by Formula (3) above (the organic boron compound of the present disclosure) in an organic solvent (hereinafter, also referred to as “mixing step”).

The type and used amount of the organic solvent are only required to be appropriately selected as described above.

The method for producing the resist composition of the present disclosure preferably includes a purification step. Examples of the purification step include, for example, after the mixing step described above, removing the solvent and washing with water or an organic solvent.

The method for producing the resist composition of the present disclosure preferably includes a solvent addition step. For example, the resist composition of the present disclosure after the purification step is preferably added to a solvent to be dissolved or dispersed.

The organic tin compound of the present disclosure used in the production of the resist composition of the present disclosure may be produced by a known method. For example, in a case of a tin-oxo cluster, a production method in which a compound represented by R^{A}—Sn(═O)—OH (where R^{A} represents an organic group) is reacted in the presence of an acid catalyst, is preferred. R^{A} is more preferably an alkyl group, an alkenyl group or an aryl group having 1 or more and 20 or less carbons, even more preferably an alkyl group having 1 or more and 20 or less carbons, particularly preferably an alkyl group having 1 or more and 10 or less carbons, and most preferably an alkyl group having 2 or more and 6 or less. The acid catalyst described above may be an organic acid or an inorganic acid and, for example, inorganic acids, such as hydrochloric acid, sulfuric acid, and phosphoric acid; p-toluenesulfonic acid, methanesulfonic acid, trifluoromethanesulfonic acid; and the like can be used.

The organic boron compound used in the production of the resist composition of the present disclosure may be produced by a known method, or a commercially available product may be used.

### Method for Forming Resist Pattern

The method for forming a pattern of the present disclosure includes: a step (i) of applying the resist composition of the present disclosure; a step (ii) of drying a coating film of the resist composition; a step (iii) of exposing the coating film of the resist composition; and a step (iv) of developing a film of the resist composition.

### Step (i)

The method for forming a resist pattern of the present disclosure includes applying the resist composition of the present disclosure (step (i)). By applying the resist composition of the present disclosure, a coating film of the resist composition of the present disclosure is formed.

In the method for forming a pattern of the present disclosure, the method of applying the resist composition of the present disclosure is not particularly limited. A resist film can be formed by using a freely chosen application method, such as an inkjet method, a spraying method, a spin coating method, a dip coating method, or a roll coating method. From the viewpoint of forming a uniform, thin film, a spin coating method is preferred.

The resist composition of the present disclosure is, for example, applied onto a substrate or the like. The substrate is not particularly limited and may have freely chosen dimension and size. Examples of the material of the substrate include silicon, SiC, a nitride semiconductor, GaAs, and AlGaAs. Furthermore, the substrate on which a resist film is formed may have a thin film processed into a desired pattern by dry etching or the like. Examples of the thin film include a polysilicon thin film, a laminated film of a polysilicon thin film and a metal thin film, a metal thin film, and an insulator thin film, such as a Si oxide film, a Si nitride film, and a Si oxynitride film. An organic film may be formed on the thin film described above. The resist composition of the present disclosure may be used for forming an upper resist film in a multilayered resist structure.

The coated amount of the resist composition of the present disclosure in the step (i) can be, for example, appropriately adjusted so that the resist film has a film thickness described below.

### Step (ii)

The method for forming a resist pattern of the present disclosure includes a step of drying a coating film of the resist composition (step (ii)). By drying the coating film of the resist composition, a coating film of the resist composition having a reduced solvent content is formed. The step (ii) is typically performed after the step (i).

In the method for forming a pattern of the present disclosure, a method of drying the coating film of the resist composition of the present disclosure is not particularly limited. For example, the organic solvent remaining in the resist film is preferably removed by heating the coating film. The heating temperature is preferably 50° C. or higher, more preferably 70° C. or higher, and even more preferably 90° C. or higher, and preferably 300° C. or lower, more preferably 250° C. or lower, and even more preferably 200° C. or lower. The heating may be performed under two or more different conditions. The heating time is preferably 10 seconds or longer, more preferably 20 seconds or longer, and even more preferably 30 seconds or longer, and preferably 300 seconds or shorter, more preferably 200 seconds or shorter, and even more preferably 150 seconds or shorter. In a case where the step (ii) is performed in the range described above, productivity of a resist film, film quality of a resist film, and adhesion to a substrate tend to improve.

The step (ii) may be performed under reduced pressure, normal pressure, or increased pressure, and may be performed in an inert gas atmosphere.

The step (ii) is preferably performed in a manner that the coating film after the drying (resist film after the drying) has an amount of remaining solvent as low as possible. For example, the step (ii) is preferably performed in a manner that the coating film after the drying has a content of the solvent of 1000 ppm or less.

Step (iii)

The method for forming a resist pattern of the present disclosure includes a step of exposing the coating film of the resist composition (step (iii)). By exposure of the coating film of the resist composition, a coating film having an exposed portion or unexposed portion cured is formed. The step (iii) is typically performed after the step (ii).

In the method for forming a pattern of the present disclosure, a method of exposing the coating film of the resist composition of the present disclosure is not particularly limited and is preferably performed by irradiation with an energy ray and through a desired mask pattern.

The energy ray may be, for example, ionizing radiation and non-ionizing radiation. The ionizing radiation is a radiation having energy adequate for ionizing an atom or molecule. Examples of the ionizing radiation include extreme ultraviolet (EUV), electron beams, ion beams, X-rays, α-rays, β-rays, γ-rays, heavy particle beams, and proton beams. The non-ionizing radiation is a radiation that does not have energy adequate for ionizing an atom or molecule. The non-ionizing radiation may be, for example, g-rays, i-rays, KrF excimer lasers, ArF excimer lasers, or F2 excimer lasers.

### Step (iv)

The method for forming a resist pattern of the present disclosure includes developing a film of the resist composition of the present disclosure (step (iv)). By the development treatment, a resist pattern can be formed. The step (iv) is typically performed after the step (iii).

In the method for forming a pattern of the present disclosure, the development of a film (resist film) of the resist composition of the present disclosure can be performed, optionally, by using water, alkali water, an organic solvent, or a liquid mixture of these. Examples of the solvent that can be used as a developer include organic solvents described above. Examples of the preferred organic solvent include aliphatic hydrocarbons, such as hexane, heptane, octane, and decane; aromatic hydrocarbons, such as toluene, ethylbenzene, xylene, mesitylene, diethylbenzene, cumene, and cymene; alcohols, such as 4-methyl-2-pentanol, 1-butanol, isopropanol, 1-propanol, and methanol; esters, such as ethyl lactate; ketones, such as acetone, methyl ethyl ketone, methyl isobutyl ketone, cyclohexanone, methyl isoamyl ketone, and 2-heptanone; ethers, such as tetrahydrofuran, dioxane, and anisole; and amines, such as tetramethylammonium hydroxide.

The developer may contain, optionally and as necessary, a viscosity modifier, a co-solubilizer, a surfactant, and the like.

The development time is preferably 10 seconds or longer, more preferably 20 seconds or longer, and even more preferably 30 seconds or longer, and preferably 300 seconds or shorter, more preferably 200 seconds or shorter, and even more preferably 100 seconds or shorter. In a case where the step (iv) is performed in the range described above, productivity of a resist film, film quality of a resist film, and adhesion to a substrate tend to improve.

The method of development is not particularly limited, and examples thereof include a dipping method, a puddle method, and a spraying method.

### Other Steps

The method for forming a pattern of the present disclosure may include an optional step other than the step (i), the step (ii), the step (iii), and the step (iv) described above. Examples of such an optional step include a step of baking a resist film after exposure to a high energy beam (step (v)), and the step (v) is typically performed after the step (iii).

### Use of Resist Composition of Present Disclosure

The resist composition of the present disclosure can be used for production of a semiconductor device, production of a mask for semiconductor production device, and the like.

### Method for Producing Semiconductor Device

The method for producing a semiconductor device includes: a step (i-b) of applying the resist composition of the present disclosure on a substrate; a step (ii-b) of drying a coating film of the resist composition to form a resist film; a step (iii-b) of exposing the coating film of the resist composition; and a step (iv-b) of developing the coating film of the resist composition. Unless otherwise particularly noted, the form and preferred form of the step (i-b), the step (ii-b), the step (iii-b), and the step (iv-b) are respectively the same as the form and preferred form of the step (i), the step (ii), the step (iii), and the step (iv) described above. The method for producing a semiconductor device may include an optional step in addition to the steps described above.

The present application claims the benefit of priority based on JP 2022-196306 filed on Dec. 8, 2022. The entire content of the specification of JP 2022-196306 filed on Dec. 8, 2022 is incorporated herein by reference.

### EXAMPLES

The present invention will be described in more detail below by way of Examples, but is not limited to only these Examples. Note that “parts” represents “parts by mass” and “%” represents “mass %” unless otherwise specified.

### Synthesis Example 1

In a 1 L four-neck flask, 20 g (95.8 mmol) of monobutyltin oxide and 5.8 g (30.3 mmol) of p-toluenesulfonic acid monohydrate were added, and then 500 mL of toluene was further added. In a nitrogen atmosphere, while water generated in the reaction system was removed by a Dean-Stark apparatus, 48 hours of heating and refluxing were performed. Thereafter, the resultant was cooled to room temperature, unreacted solids were filtered to be separated, and the solution was dried and solidified under reduced pressure. To the resulting solid, 1,4-dioxane was added for purification by recrystallization, and then filtration was performed. Thus, 14 g of tin-oxo cluster p-toluenesulfonate ([(n-C₄H₉Sn)₁₂(μ₃—O)₁₄(μ₂-OH)₆](4-CH═C₆H₄SO₃)₂), which was a target material, was prepared.

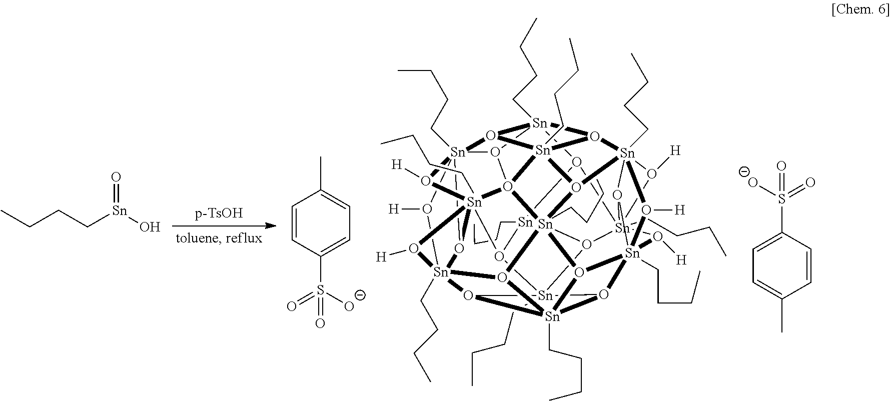

### Synthesis Example 2

In a 200 mL eggplant flask, 11.4 g of the tin-oxo cluster p-toluenesulfonate prepared in Synthesis Example 1 was added, and 58 mL of isopropyl alcohol was added to dissolve the tin-oxo cluster p-toluenesulfonate. While being heated and agitated at 40° C., a solution in which 5.5 g of 15 mass % aqueous tetramethylammonium hydroxide solution, 5.7 mL of isopropyl alcohol, and 4 mL of water were mixed was gradually added dropwise. After the completion of dropwise addition, agitation was performed for 10 minutes, and then the mixture was cooled to room temperature.

The mixture was allowed to stand at room temperature for 1 day, and the resulting solids were filtered and washed with acetonitrile, and thus 4.5 g of tin-oxo cluster hydroxide ([(n-C₄H₉Sn)₁₂(μ₃-O)₁₄(μ₂-OH)₆](OH)₂) (compound A), which was a target material, was prepared.

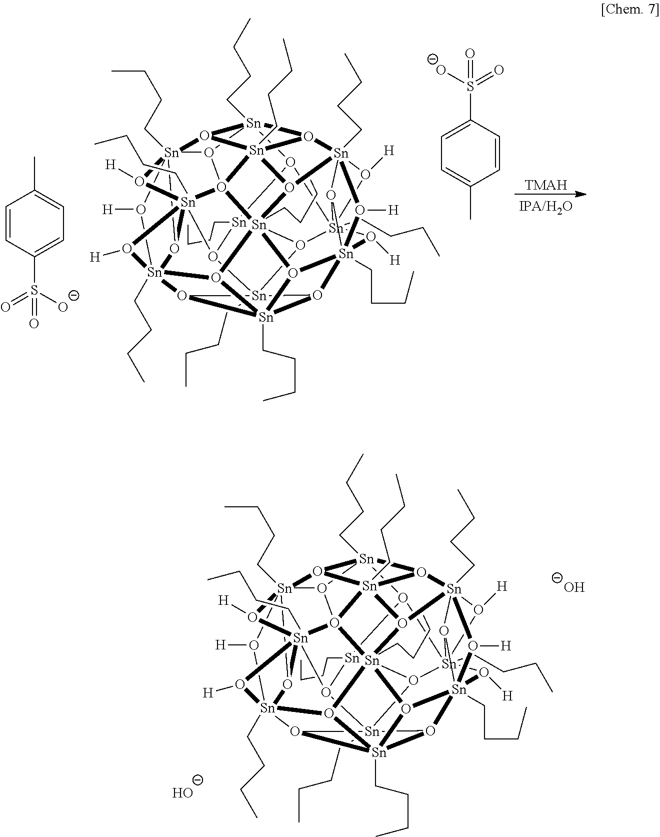

### Example 1

### Resist Application

A resist solution was prepared by dissolving the compound A (54 mg) and 4-(trifluoromethyl)phenylboronic acid (6 mg) in 2-butanone in a manner that the solid content concentration became 20 mg/mL. On a Si substrate cut into a 15 mm×15 mm square, this resist solution was dropped through a polytetrafluoroethylene (PTFE) membrane filter with a pore size of 0.2 μm, spin-coated at 1500 rpm for 45 seconds, and then subjected to heat treatment at 90° C. for 60 seconds. Thus, a resist film was prepared.

### Exposure

The resulting resist film was irradiated with UV rays by using a high pressure mercury lamp (illuminance at the wavelength of 365 nm: 52 mW/cm²) for 15 seconds. At this time, a half of the substrate was covered with aluminum foil to shield the light in a manner that an exposed portion and an unexposed portion were formed.

### Development

After the exposed substrate was developed by being immersed in ethylbenzene for 30 seconds, drying was performed by blowing compressed air. After the drying, while the resist film remained on the exposed portion, the resist film was removed in the unexposed portion, and negative contrast was observed.

Note that, in Example 1 described above, the exposure amount was 780 mJ/cm² (=52 mW/cm²×15 seconds); however, even when the illuminance and the time were changed to set the exposure amount to 260 mJ/cm², 1500 mJ/cm², 3100 mJ/cm², 4700 mJ/cm², 6300 mJ/cm², 9400 mJ/cm², or 12500 mJ/cm², while the resist film remained on the exposed portion, the resist film was removed in the unexposed portion, and negative contrast was observed.

### Comparative Example 1

The compound A was dissolved in toluene in a manner that the solid content concentration became 20 mg/mL, the resist application, exposure, and development were performed in the same manner as in Example 1. On the substrate after the development, the resist film remained on both of the exposed portion and the unexposed portion, and contrast was not observed.

### Comparative Example 2

The resist application, exposure, and development were performed in the same manner as in Comparative Example 1 except for using 2-heptanone as the developer in place of the ethylbenzene. On the substrate after the development, the resist film did not remain on both of the exposed portion and the unexposed portion, and contrast was not observed.

1. A resist composition comprising:
an organic tin compound; and
an organic boron compound represented by a formula: 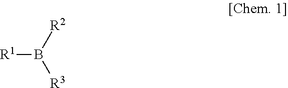
where R¹, R², and R³ each independently represent an organic group that bonds to boron by a carbon atom, an oxygen-containing organic group that bonds to boron by an oxygen atom, or OH; the oxygen-containing organic group may contain a boron atom; and two groups selected from the group consisting of R¹, R², and R³ may link to form a ring structure.

2. The resist composition according to claim 1, wherein the organic tin compound contains a Sn—O bond and a Sn—C bond.

3. The resist composition according to claim 1, wherein the organic tin compound is a tin cluster.

4. The resist composition according to claim 3, wherein the tin cluster contains a cation-type tin cluster and a counter anion.

5. The resist composition according to claim 1, wherein at least one of the R¹, the R², or the R³ is an organic group that bonds to boron by a carbon atom, and at least one of the R¹, the R², or the R³ is an oxygen-containing organic group that bonds to boron by an oxygen atom.

6. The resist composition according to claim 1, wherein the organic boron compound contains at least one type selected from the group consisting of boronic acid, boronate ester, and boroxine.

7. A method for forming a resist pattern, the method comprising:
a step (i) of applying the resist composition described in claim 1;
a step (ii) of drying a coating film of the resist composition;
a step (iii) of exposing the coating film of the resist composition; and
a step (iv) of developing a film of the resist composition.

8. A method for producing a resist composition, the method comprising a step of mixing, in an organic solvent, an organic tin compound and an organic boron compound represented by a formula: 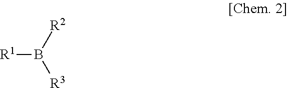
where R¹, R², and R³ each independently represent an organic group that bonds to boron by a carbon atom, an oxygen-containing organic group that bonds to boron by an oxygen atom, or OH; the oxygen-containing organic group may contain a boron atom; and two groups selected from the group consisting of R¹, R², and R³ may link to form a ring structure.
